(19) United States
(12) Patent Application Publication
(10) Pub. No.: US 2006/0070769 A1
(43) Pub. Date: Apr. 6, 2006

(54) Printed circuit board and method of fabricating same

(75) Inventor: Seung Chul Kim, Chungcheongbuk-do (KR)

Correspondence Address: DARBY & DARBY P.C., P. O. BOX 5257, NEW YORK, NY, 10150-5257, US

(73) Assignee: Samsung Electro-Mechanics Co., Ltd., Kyunggi-do (KR)

(21) Appl. No.: 11/064,449

(22) Filed: Feb. 22, 2005

(30) Foreign Application Priority Data
Oct. 5, 2004 (KR) 2004-79132

(51) Int. Cl. H05K 1/11; H01R 12/04

(52) U.S. Cl. 174/262

(57) ABSTRACT

Disclosed is a PCB which includes an insulating layer. At least one via hole is formed through the insulating layer. A first electroless plating layer is formed on a wall of the via hole and on at least one side of the insulating layer so as to have a predetermined pattern, and is etched at its edge portion corresponding to an edge portion of the pattern in a dimension that is in proportion to a thickness thereof. A second electroless plating layer is formed on the first electroless plating layer. An electrolytic plating layer is formed on the second electroless plating layer, and is etched at its edge portion in a dimension that is in proportion to the thickness of the first electroless plating layer.

### INCORPORATION BY REFERENCE

The present application claims priority under 35 U.S.C. §119 to Korean Patent Application No. 2004-79132 filed on Oct. 5, 2004. The content of the application is incorporated herein by reference in its entirety.

### BACKGROUND OF THE INVENTION

1. Field of the Invention

The present invention relates, in general, to a printed circuit board (PCB) and a method of fabricating the same and, more particularly, to a PCB and a method of fabricating the same, in which an electroless copper plating process is repeated twice to prevent interruption of an internal circuit of a via hole and to form a fine circuit pattern.

2. Description of the Prior Art

As a technology for coping with a highly dense semiconductor chip and a high signal transmission speed of the semiconductor chip, demand for direct mounting of a semiconductor chip on a PCB is lately growing instead of CSP (chip-sized package) or wire bonding mounting technologies. To directly mount the semiconductor chip on the PCB, it is necessary to develop a highly dense and reliable PCB capable of dealing with a highly dense semiconductor.

Requirements for a highly dense and reliable PCB have a close relationship with the specifications of a semiconductor chip, and are exemplified by fineness of circuits, excellent electric characteristics, structures providing high-speed signal transmission, high reliability, and high performance. There remains a need to develop a PCB technology of forming fine circuit patterns and micro-via holes so as to solve such requirements.

Generally, a process of forming a circuit pattern on a PCB is classified into a subtractive process, a full additive process, and a semi-additive process. Of them, the semi-additive process is being pursued with interest, which can make the circuit pattern fine.

FIGS. 1a to 1g are sectional views illustrating a procedure of fabricating a conventional PCB, which shows the semi-additive process, and FIGS. 2a and 2b are sectional views illustrating a via hole formed through the procedure of FIGS. 1a to 1g. In the drawings, only one side of the PCB is illustrated. However, in practice, both sides of the PCB are processed.

As shown in FIG. 1a, a copper clad laminate 100, in which a circuit pattern 112 and a lower land 113 of the via hole are formed on an insulating resin layer 111, is provided. Subsequently, an insulating layer 120 is laminated on the copper clad laminate 100.

As shown in FIG. 1b, the insulating layer 120 is processed using a laser to form the via hole (a) to provide a circuit connection between the layers.

As shown in FIG. 1c, an electroless copper plating layer 130 is formed to a thickness of about 1 μm or more on the insulating layer 120, a wall 121 of the via hole, and the lower land 113 so as to achieve electric connection between the layers and to form the circuit pattern on a surface of the insulating layer 120.

As shown in FIG. 1d, a dry film 150 is applied on the electroless copper plating layer 130, exposed, and developed to form a plating resist pattern, in which a circuit pattern 131, a wall 132 of the via hole, an upper land 133, and a lower land 134 are partially developed, in the dry film 150.

As shown in FIG. 1e, an electrolytic copper plating layer 141, 142 is formed on portions of the circuit pattern 131, the wall and the bottom of the via hole (a), the upper land 133, and the lower land 134, on which the plating resist pattern is not formed, to a thickness of about 10-20 μm.

As shown in FIG. 1f, the dry film 150 is stripped and thus removed.

As shown in FIG. 1g, an etchant is sprayed onto the electroless copper plating layer 130 and the electrolytic copper plating layer 141, 142 to remove a portion of the electroless copper plating layer 130 other than the circuit pattern 131, 141, and via hole regions 132, 133, 134, 142.

In the PCB fabricated using the semi-additive process, an electroless plating liquid does undesirably flow in the via hole (a) in FIG. 1c. Accordingly, as shown in FIG. 2a, the electroless copper plating layer 132 formed on the wall 121 of the via hole may be thinner than the electroless copper plating layer 133 formed on the insulating layer 120, or the electroless copper plating layer may not be formed on a portion of the wall of the via hole. Hence, as shown in FIG. 2b, undesirably, an internal circuit of the via hole (a) is interrupted after the electrolytic copper plating layer 142 is formed.

To prevent the interruption of the via hole (a) connection, the electroless copper plating layer 130 may be thickly formed in FIG. 1c. However, since an etching process is conducted for a relatively long time in order to remove unnecessary electrolytic copper plating layer 130 in FIG. 1g, the circuit pattern 131, 141 (particularly, edge portions of the circuit pattern 131, 141) is over-etched. Therefore, delamination of the circuit pattern 131, 141 occurs, or morphology of the circuit pattern 131, 141 is not flat.

To avoid the above problems, Japanese Pat. Laid-Open Publication No. 2002-252466 suggests the following process.

FIGS. 3a to 3e are sectional views illustrating the fabrication of another conventional PCB. As in the procedure of FIGS. 1a to 1g, only one side of the PCB is illustrated in FIGS. 3a to 3e, but in practice, both sides of the PCB are processed.

As shown in FIG. 3a, an epoxy resin layer 13 is laminated on a double-sided copper clad laminate 11, in which a circuit pattern 12 is formed on a surface of an epoxy layer reinforced with a glass fiber, and a via hole 15 is then formed using a laser. Subsequently, the double-sided copper clad laminate 11 is dipped in a mixed solution of 10% H₂SO₄ and 10% H₂O₂ to form an activated region 17.

As shown in FIG. 3b, an electroless copper plating layer 18 is formed on the activated region 17 acting as a self-catalyst.

As shown in FIG. 3c, a Pd catalyst 19 adheres to the circuit pattern and an exposed portion of the epoxy resin layer 13 of the double-sided copper clad laminate 11.

As shown in FIG. 3d, the double-sided copper clad laminate 11 is dipped in a copper sulfate-based electroless copper plating solution to form an electroless copper plating layer 20 on the circuit pattern and the exposed portion of the epoxy resin layer 13.

As shown in FIG. 3e, an electrolytic copper plating layer 21 is formed on the electroless copper plating layer 20 of the double-sided copper clad laminate 11.

In the PCB disclosed in Japanese Pat. Laid-Open Publication No. 2002-252466 as described above, the electroless copper plating layer 18 is formed using the activated region 17, preventing the internal circuit of the via hole 15 from being interrupted.

However, in the PCB disclosed in Japanese Pat. Laid-Open Publication No. 2002-252466, since the circuit pattern is formed on the electroless copper plating layer 20 and the electrolytic copper plating layer 21 using a subtractive process, it is more difficult to make a fine circuit pattern than when using the semi-additive process.

To avoid the above disadvantages, in a method of fabricating the PCB disclosed in Japanese Pat. Laid-Open Publication No. 2002-252466, the circuit pattern is formed using the semi-additive process. However, since the thick electroless copper plating layer 20 (growing for 30 min at a growth speed of about 10 μm/h) must be etched, undesirably, the circuit pattern is over-etched.

### SUMMARY OF THE INVENTION

Therefore, the present invention has been made keeping in mind the above disadvantages occurring in the prior arts, and an object of the present invention is to provide a PCB, in which an internal circuit of a via hole is not interrupted, and a method of fabricating the same.

Another object of the present invention is to provide a PCB, in which a fine circuit pattern is formed, and a method of fabricating the same.

The above objects can be accomplished by providing a PCB which includes an insulating layer. At least one via hole is formed through the insulating layer. A first electroless plating layer is formed on a wall of the via hole and on at least one side of the insulating layer so as to have a predetermined pattern, and is etched at its edge portion corresponding to an edge portion of the pattern in a dimension that is in proportion to a thickness thereof. A second electroless plating layer is formed on the first electroless plating layer. An electrolytic plating layer is formed on the second electroless plating layer, and is etched at its edge portion in a dimension that is in proportion to the thickness of the first electroless plating layer.

It is preferable that the first electroless plating layer be thinner than the second electroless plating layer.

It is preferable that a thickness of the first electroless plating layer be about 0.1-0.5 μm and a thickness of the second electroless plating layer be about 1-5 μm.

It is preferable that each of the first electroless plating layer, the second electroless plating layer, and the electrolytic plating layer comprises a material, selected from the group consisting of Cu, Au, Ni, Sn, and an alloy thereof, as a main component.

Furthermore, the present invention provides a method of fabricating a PCB, which includes (A) laminating an insulating layer on a substrate, on which a circuit pattern is formed, and forming a via hole through the insulating layer for connection to the circuit pattern; (B) forming a first electroless plating layer on an exposed portion of the circuit pattern, the insulating layer, and a wall of the via hole; (C) forming a predetermined plating resist pattern on the first electroless plating layer, and forming a second electroless plating layer on a portion of the first electroless plating layer, on which the plating resist pattern is not formed; (D) forming an electrolytic plating layer on the second electroless plating layer, and removing the plating resist pattern; and (E) removing the remaining portion of the first electroless plating layer, on which the second electroless plating layer and the electrolytic plating layer are not formed.

It is preferable that the first electroless plating layer be formed using a catalyst precipitation process in the step (B).

It is preferable that the first electroless plating layer be formed using a sputtering process in the step (B).

It is preferable that the second electroless plating layer be formed using the first electroless plating layer as a self-catalyst in the step (C).

It is preferable that the electrolytic plating layer be formed using the first electroless plating layer as an incoming line for plating in the step (D).

It is preferable that the first electroless plating layer be formed thinner than the second electroless plating layer of the step (C) in the step (B).

It is preferable that a thickness of the first electroless plating layer be about 0.1-0.5 μm and a thickness of the second electroless plating layer be about 1-5 μm.

It is preferable that each of the first electroless plating layer, the second electroless plating layer, and the electrolytic plating layer comprise a material, selected from the group consisting of Cu, Au, Ni, Sn, and an alloy thereof, as a main component.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1g are sectional views illustrating a procedure of fabricating a conventional PCB;

FIGS. 2a and 2b are sectional views illustrating a via hole formed through the procedure of FIGS. 1a to 1g;

FIGS. 3a to 3e are sectional views illustrating the fabrication of another conventional PCB;

FIGS. 4a and 4j are sectional views illustrating the fabrication of a PCB according to the present invention; and

FIG. 5 is a partially enlarged view of a portion B which is marked by a dotted circle of FIG. 4j.

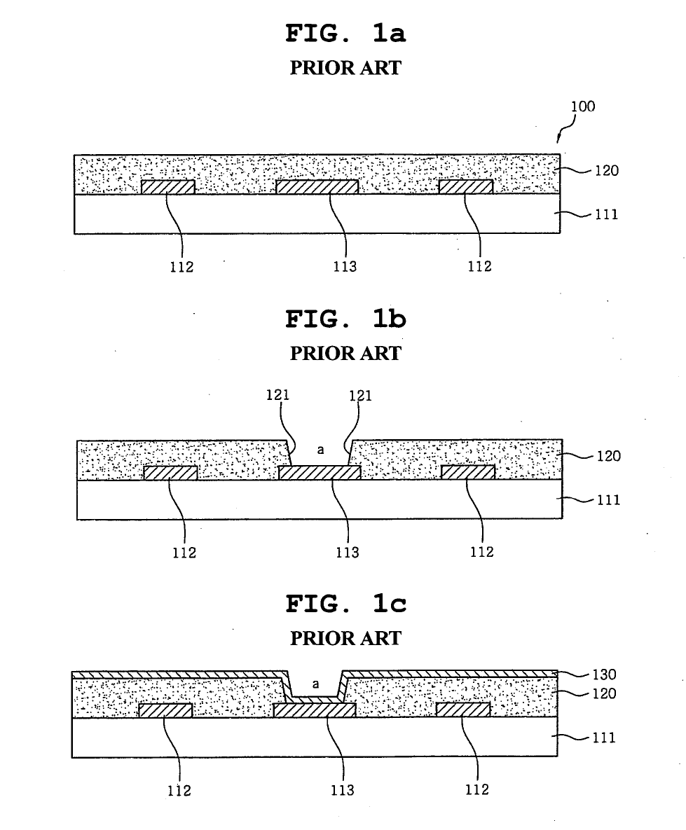

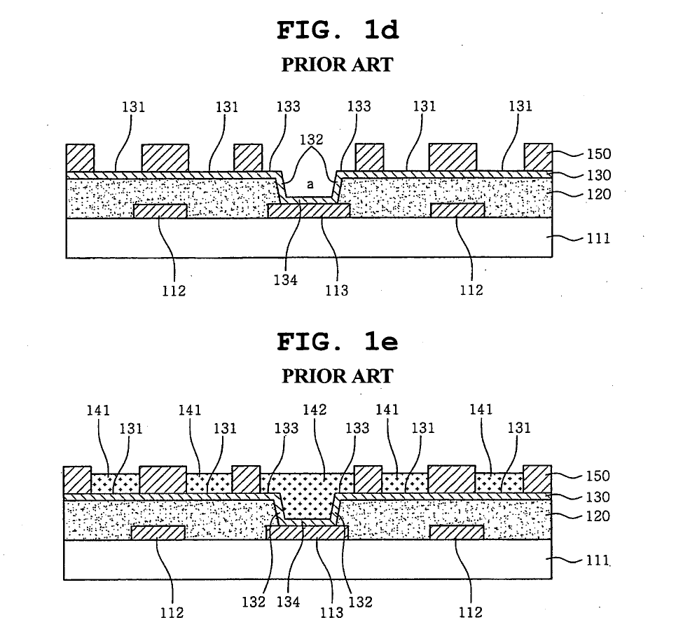

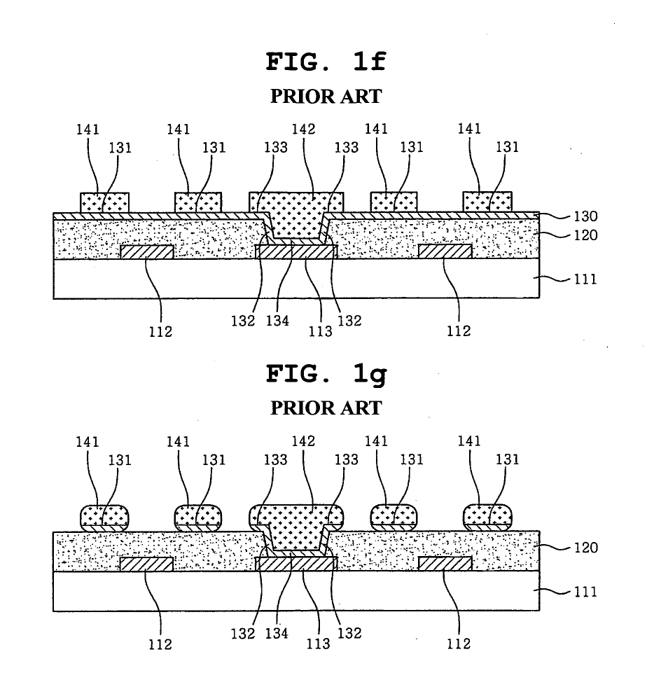

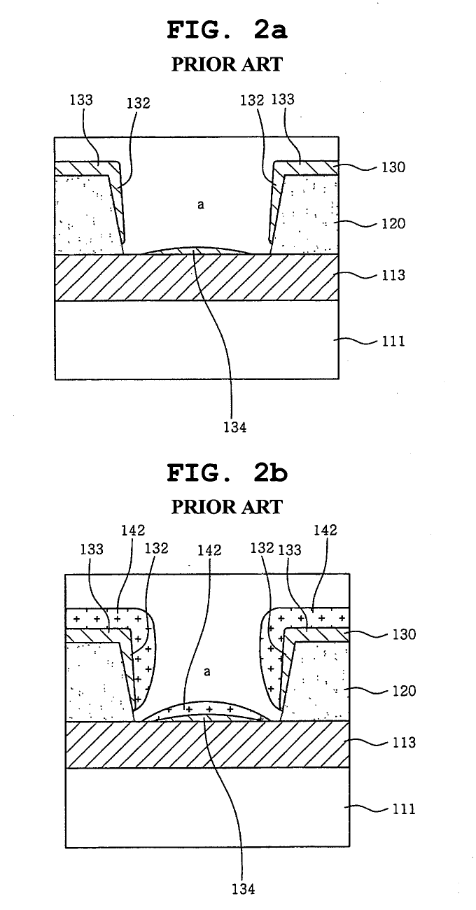

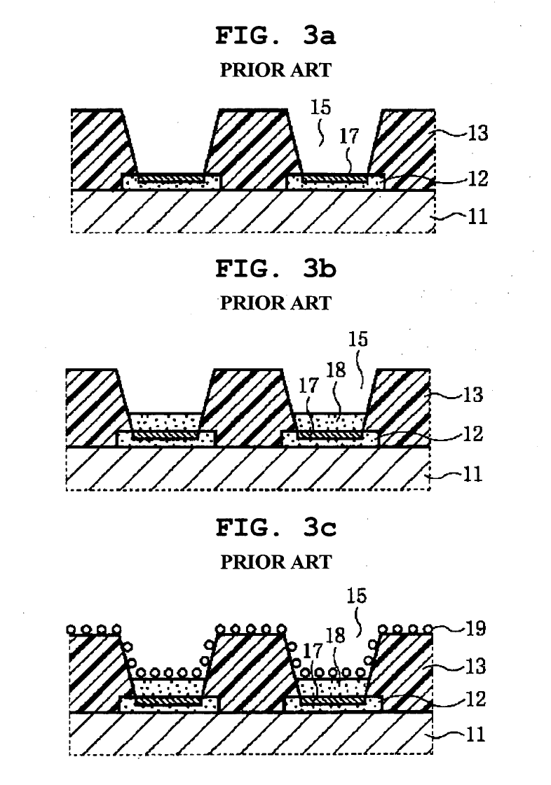

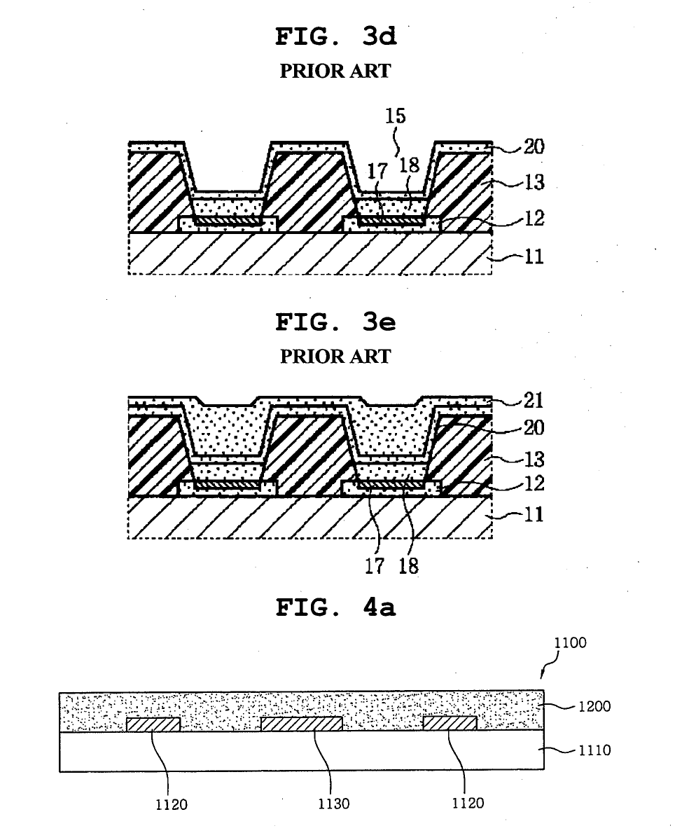

### DETAILED DESCRIPTION OF THE INVENTION

Hereinafter, a detailed description will be given of a PCB and a method of fabricating the same according to the present invention with reference to the drawings.

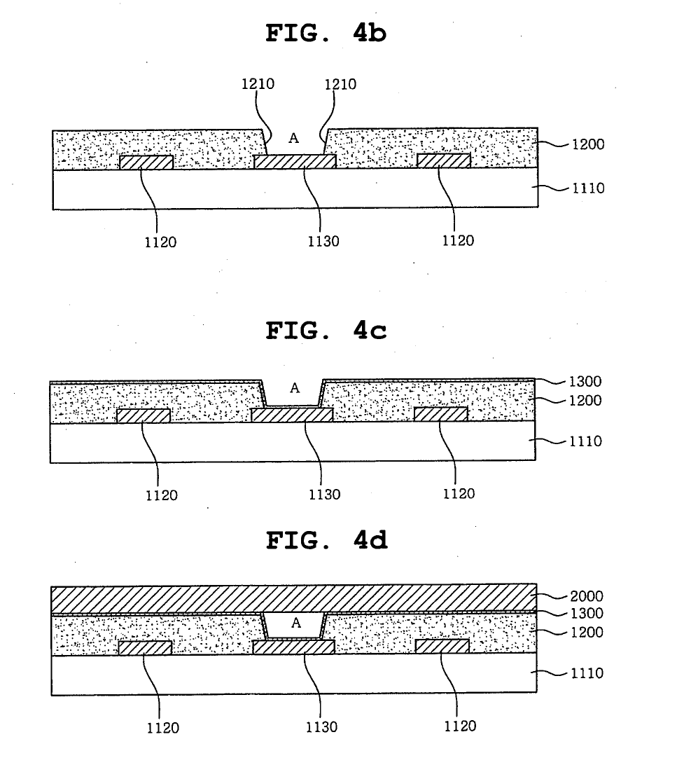

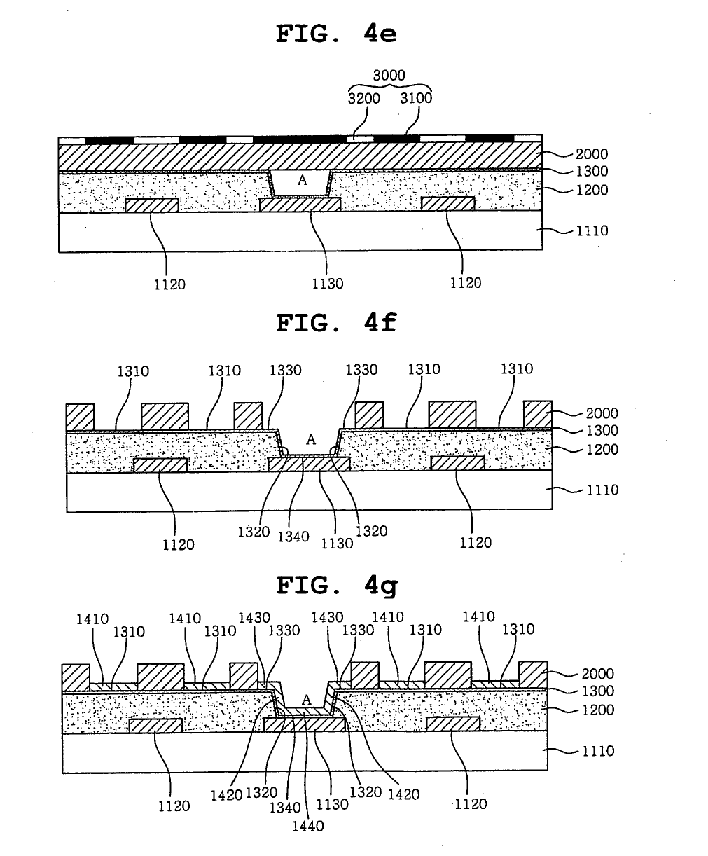

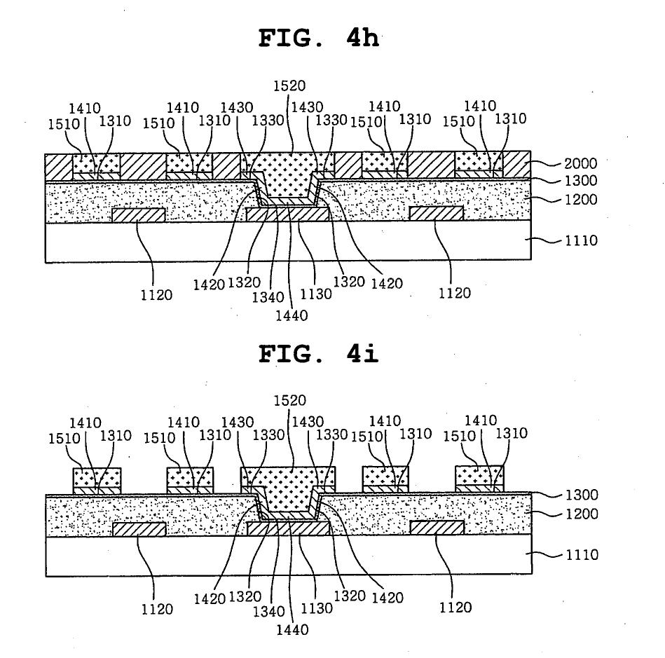

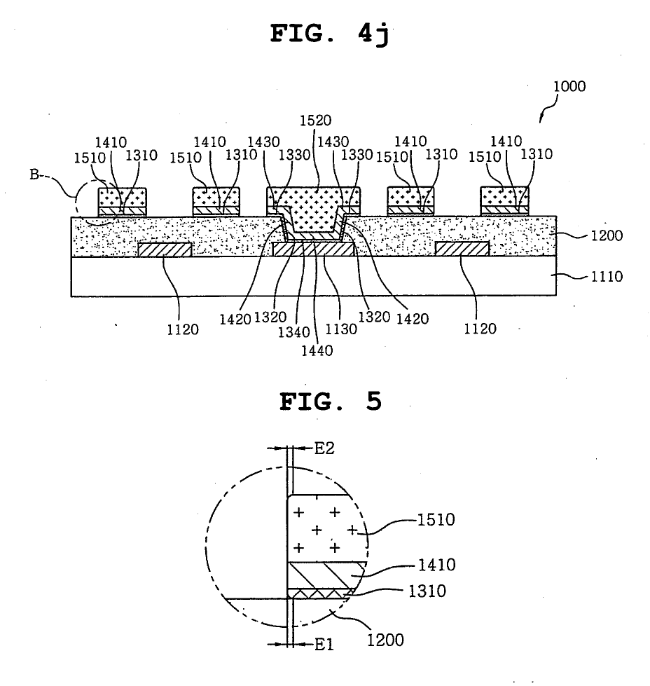

FIGS. 4a and 4j are sectional views illustrating the fabrication of a PCB according to the present invention, and FIG. 5 is a partially enlarged view of a portion B which is marked by a dotted circle of FIG. 4j. In the drawings, only one side of the PCB is illustrated, but in practice, both sides of the PCB are processed.

As shown in FIG. 4a, a substrate, that is, a copper clad laminate 1100, is provided, in which a first circuit pattern 1120 and a lower land 1130 are formed on an insulating resin layer 1110. Subsequently, an insulating layer 1200 (for example, prepreg) is laminated on the substrate 1100.

In this respect, the copper clad laminate used as the substrate 1100 may be classified into a glass/epoxy copper clad laminate, a heat-resistant resin copper clad laminate, a paper/phenol copper clad laminate, a high-frequency copper clad laminate, a flexible copper clad laminate, and a composite copper clad laminate, depending on the application. However, it is preferable to use the glass/epoxy copper clad laminate, in which copper foil layers are formed on both sides of the insulating resin layer, and which is most frequently employed in the course of fabricating PCBs.

In the present invention, the substrate has a structure in which a circuit layer is formed on one side of the substrate 1100. However, a substrate 1100 having a multi-layered structure, in which a predetermined circuit pattern, a via hole and the like are formed on an internal layer, may be used depending on the purpose or application.

As shown in FIG. 4b, the insulating layer 1200 is bored using a laser to form a via hole (A) for circuit connection between the layers.

In this regard, the laser may be exemplified by a YAG (yttrium aluminum garnet) laser and a carbon dioxide (CO₂) laser.

In the present invention, after formation of the via hole (A) using the laser, it is preferable to further conduct a desmear process so as to remove a smear which is formed on a wall 1210 of the via hole by melting the insulating layer 1200 due to heat generated in the course of forming the via hole.

As shown in FIG. 4c, a very thin first electroless copper plating layer 1300 is formed on the insulating layer 1200, wall 1210 of the via hole, and a lower land 1130 so as to electrically connect the layers to each other and to form the circuit pattern on a surface of the insulating layer 1200.

At this time, it is preferable that the first electroless copper plating layer 1300 be about 0.1-0.5 μm in thickness. When the thickness of the first electroless copper plating layer 1300 is less than about 0.1 μm, the first electroless copper plating layer 1300 may not be formed on a portion of the resulting substrate, affecting a subsequent electrolytic copper plating process. On the other hand, when the thickness of the first electroless copper plating layer 1300 is more than about 0.5 μm, since the first electroless copper plating layer 1300 is thick, over-etching may occur in an etching process.

For example, the first electroless copper plating layer 1300 may be formed using a catalyst precipitation method including a degreasing step, a soft etching step, a pre-catalyst treating step, a catalyst treating step, an acceleration step, an electroless copper plating step, and an anti-oxidizing step.

In the degreasing step, oxides, impurities, and particularly oils and fats are removed from the surfaces of the insulating layer 1200, the wall 1210 of the via hole, and the lower land 1130 using a chemical containing acid or alkaline surfactants, and the resulting substrate is rinsed to completely remove the surfactants therefrom.

The soft etching step makes the surfaces of the insulating layer 1200, the wall 1210 of the via hole, and the lower land 1130 slightly rough (for example, a roughness of about 1-2 μm) to uniformly deposit copper particles on the surfaces during the electroless copper plating step, and to remove contaminants which are not removed during the degreasing step.

In the pre-catalyst treating step, the substrate 1100 is dipped in a dilute first catalyst-containing chemical to prevent a second catalyst-containing chemical used in the catalyst treating step from being contaminated or to prevent the concentration of the second catalyst-containing chemical from changing. Moreover, because the substrate 1100 is preliminarily dipped in the first chemical, having the same components as the second chemical, prior to treating the substrate using the second chemical, the treating of the substrate using the catalyst is preferably achieved. At this stage, it is preferable that the chemical diluted in a concentration of 1-3% be used in the pre-catalyst treating step.

In the catalyst treating step, catalyst particles are applied on the surfaces of the insulating layer 1200, the wall 1210 of the via hole, and the lower land 1130. The catalyst particles may be preferably exemplified by a Pd-Sn compound, and Pd₂⁻ dissociated from the Pd-Sn compound helps promote the plating of the substrate in conjunction with Cu₂⁺ plated on the substrate.

During the electroless copper plating step, the first electroless copper plating layer 1300 is formed on the insulating layer 1200, the wall 1210 of the via hole, and the lower land 1130. In this stage, it is preferable that a plating solution contain CuSO₄, HCHO, NaOH, and a stabilizer. It is important to control the composition of the plating solution because chemical reactions constituting the plating process must maintain an equilibrium state in order to continuously conduct the plating process. To desirably maintain the composition of the plating solution, it is necessary to properly replenish each component constituting the plating solution, to mechanically agitate the plating solution, and to smoothly operate a cycling system of the plating solution. Furthermore, it is necessary to use a filtering device for removing byproducts resulting from the reaction, and the removal of the byproducts using the filtering device extends the life of the plating solution.

An anti-oxidizing layer is formed on a copper clad to prevent oxidation of the copper clad caused by alkaline components remaining after the electroless copper plating step during the anti-oxidizing step.

Alternatively, the formation of the first electroless copper plating layer 1300 may be achieved using a sputtering method, in which gas ion particles (for example, Ar⁺) generated by plasma or the like collide with a copper target to form the first electroless copper plating layer 1300 on the insulating layer 1200, the wall 1210 of the via hole, and the lower land 1130.

As shown in FIG. 4d, a dry film 2000 is formed on the first electroless copper plating layer 1300.

The dry film 2000 includes three layers, that is, a cover film, a photoresist film, and a Mylar film, and the photoresist film substantially acts as a resist.

As shown in FIG. 4e, an art work film 3000, having a predetermined pattern printed thereon, is attached to the dry film 2000, and then exposed to ultraviolet rays. The ultraviolet rays are not transmitted through a black portion 3100 of the art work film 3000, on which the pattern is printed, but through the remaining portion 3200 of the art work film 3000, on which the pattern is not printed, hardening the dry film 2000 below the art work film 3000.

The predetermined pattern includes a second circuit pattern, the wall and the bottom of the via hole, and an upper land of the via hole to be formed in the subsequent processes.

As shown in FIG. 4f, after the art work film 3000 is removed, the substrate 1100 is dipped in a developing solution to remove the unhardened portions of the dry film 2000 from portions of the electroless copper plating layer 1300, such as the second circuit pattern 1310, the wall 1320 of the via hole, the upper land 1330, and the lower land 1340. The remaining hardened portion of the dry film 2000 forms a plating resist pattern.

In this regard, examples of the developing solution include a sodium carbonate (Na₂CO₃) aqueous solution or a potassium carbonate (K₂CO₃) aqueous solution.

As shown in FIG. 4g, a second electroless copper plating layer 1410, 1420, 1430, 1440 is formed on the second circuit pattern 1310, the upper land 1330, the wall 1320 of the via hole, and the lower land 1340 using the patterned dry film 2000 as a plating resist.

At this stage, it is preferable that the second electroless copper plating layer 1410, 1420, 1430, 1440 be about 1-5 μm in thickness. When the thickness of the second electroless copper plating layer 1410, 1420, 1430, 1440 is less than about 1 μm, since an electroless plating liquid undesirably flows in the via hole, the second electroless copper plating layer 1420 may not be formed on a portion of the wall of the via hole. In this case, undesirably, an internal circuit of the via hole (A) may be interrupted after an electrolytic copper plating layer is formed. On the other hand, when the thickness of the second electroless copper plating layer 1410, 1420, 1430, 1440 is more than about 5 μm, it undesirably takes a long time to form the second electroless copper plating layer 1410, 1420, 1430, 1440. Additionally, since the electroless copper plating layer has physical properties poorer than the electrolytic copper plating layer, it is preferable to form the second electroless copper plating layer as thinly as possible so that the internal circuit of the via hole is not interrupted.

In the present invention, the formation of the second electroless copper plating layer 1410, 1420, 1430, 1440 may be conducted using the first electroless copper plating layer 1310, 1320, 1330, 1340 as a self-catalyst. Therefore, the second electroless copper plating layer 1410, 1420, 1430, 1440 may be directly formed on the first electroless copper plating layer 1310, 1320, 1330, 1340 of the second circuit pattern, the wall of the via hole, the upper land, and the lower land while the catalyst treating step is not conducted. This means that many pretreatments may be omitted in the course of forming the second electroless copper plating layer 1410, 1420, 1430, 1440.

The second electroless copper plating layer 1410, 1420, 1430, 1440 is formed on the second circuit pattern 1310, the wall 1320 of the via hole, the upper land 1330, and the lower land 1340 using a plating solution which contains CuSO₄, HCHO, NaOH, and a stabilizer. As in the formation of the first electroless copper plating layer 1300, it is important to control the composition of the plating solution because chemical reactions constituting the second copper plating process must maintain an equilibrium state in order to continuously conduct the plating process. To desirably maintain the composition of the plating solution, it is necessary to properly replenish each component constituting the plating solution, to mechanically agitate the plating solution, and to smoothly operate a cycling system of the plating solution. Furthermore, it is necessary to use a filtering device for removing byproducts resulting from the reaction, and the removal of the byproducts using the filtering device extends the life of the plating solution.

As shown in FIG. 4h, an electrolytic copper plating layer 1510, 1520 is formed on a portion of the second electroless copper plating layer 1410, 1420, 1430, 1440, such as the second circuit pattern, the wall and the bottom of the via hole, the upper land, and the lower land, on which the plating resist pattern of the dry film 2000 is not formed.

After the substrate 1100 is dipped into a copper plating tub, the electrolytic copper plating is then conducted using a D.C. rectifier to form the electrolytic copper plating layer 1510, 1520. Preferably, the electrolytic copper plating is conducted in such a way that after an area to be plated is calculated, a proper amount of electricity is applied to the D.C. rectifier to achieve the deposition of copper.

The electrolytic copper plating process is advantageous in that physical properties of the electrolytic copper plating layer are superior to those of the electroless copper plating layer and it is easy to form a thick copper plating layer.

An additional incoming line for the copper plating may be used to form the electrolytic copper plating layer 1510, 1520. However, in the present invention, it is preferable to use the first electroless copper plating layer 1300 as the incoming line to form the electrolytic copper plating layer 1510, 1520.

As shown in FIG. 4i, the dry film 2000 is stripped from the substrate 1100 and thus removed.

At this time, the dry film 2000 is removed using a stripping solution containing sodium hydroxide (NaOH) or potassium hydroxide (KOH).

In the steps of FIGS. 4d to 4i, the dry film 2000 is used as the plating resist. However, a liquid photosensitive substance may be used as the plating resist.

In this case, the liquid photosensitive substance, which is to be exposed to ultraviolet rays, is applied on the insulating layer 1200, and then dried. Subsequently, the photosensitive substance is exposed and developed using the patterned artwork film 3000, which includes the second circuit pattern, the via hole, and the upper land, thereby forming a predetermined pattern thereon. Next, the patterned photosensitive substance is used as the plating resist, and the electroless and electrolytic copper plating processes are sequentially conducted, thereby forming the second electroless copper plating layer 1410, 1420, 1430, 1440 and the electrolytic copper plating layer 1510, 1520 on the second circuit pattern 1310, the wall 1320 of the via hole, the upper land 1330, and the lower land 1340. The photosensitive substance is then removed. The application of the liquid photosensitive substance is implemented by a dip coating process, a roll coating process, an electro-depositing process or the like.

Compared to the use of the dry film 2000, the use of the liquid photosensitive substance is advantageous in that since it is possible to form a thinner layer, a finer circuit pattern can be formed. Another advantage is that when a surface of the insulating layer 1200 is uneven, it is possible to flatten the surface by filling recesses of the insulating layer.

As shown in FIG. 4j, an etchant is sprayed onto the substrate 1100 to remove the remaining portion of the first electroless copper plating layer 1300 other than the second circuit pattern, the via hole, and the upper land.

Referring to FIG. 5, thicknesses (E1, E2) of etched edge portions of the first electroless copper plating layer 1300 and the electrolytic copper plating layer 1510 of the second circuit pattern are proportional to a thickness of the first electroless copper plating layer 1300. Accordingly, since the first electroless copper plating layer 1300 is very thin (about 0.1-0.5 μm), the amount of etched materials of the first electroless copper plating layer 1300 and the electrolytic copper plating layer 1510 of the second circuit pattern is very small.

Subsequently, a procedure of laminating the insulating layer, and of forming the via hole, the first electroless copper plating layer, the second electroless copper plating layer, and the electrolytic copper plating layer is repeated to form a structure having desired layers. Next, a solder resist forming process, a nickel/gold plating process, and an external part forming process are implemented, thereby creating the PCB 1000 according to the present invention.

As shown in FIG. 4j, in the PCB 1000 according to the present invention, since the first electroless copper plating layer 1300 used as the incoming line for the copper plating is very thin (about 0.1-0.5 μm), the second circuit pattern 1310, 1410, 1510 (particularly, edge portions of the second circuit pattern 1310, 1410, 1510) is scarcely etched. Accordingly, it can be seen that flat morphology of the circuit pattern can be assured without delamination of the circuit pattern in the course of forming a fine circuit pattern (a line width of about 10 μm or less).

Furthermore, in the PCB 1000 according to the present invention, since the second electroless copper plating layer 1420, 1440 having a desired thickness (about 1-5 μm) is formed in the via hole, an internal circuit of the via hole is not interrupted after the electrolytic copper plating layer 1510, 1520 is formed.

Meanwhile, in the present invention, sections of the first electroless copper plating layer 1310, 1320, 1330, 1340, the second electroless copper plating layer 1410, 1420, 1430, 1440, and the electrolytic copper plating layer 1510, 1520, which are sequentially formed on the second circuit pattern, the wall of the via hole, the upper land, and the lower land of the PCB 1000 according to the present invention, are observed using an analysis device, such as SEM (scanning electron microscope), thereby confirming a three-layered structure of the copper plating layer.

Furthermore, the three-layered structure of the copper plating layer of the PCB 1000 according to the present invention is not limited to a layer made of pure copper, but means a plating layer consisting mostly of copper. This is confirmed by analyzing a chemical composition of the layer using an analysis device, such as EDAX (energy dispersive analysis of X-rays), which is usually provided in the scanning electron microscope.

Additionally, the three-layered structure of the copper plating layer of the PCB 1000 according to the present invention is not limited to a layer made only of copper (Cu), but may be a three-layered structure consisting mostly of a conductive material, such as gold (Au), nickel (Ni), and tin (Sn), according to the purpose and the application.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

As described above, a PCB and a method of fabricating the same according to the present invention are advantageous in that since a first electroless copper plating layer is very thin, the amount of an etched material of a copper plating layer of a circuit pattern is minimized.

Another advantage of the present invention is that the amount of the etched material of the copper plating layer is reduced, preventing delamination of the circuit pattern due to over-etching, resulting in the formation of a very fine circuit pattern.

Still another advantage of the present invention is that the amount of the etched material of the copper plating layer is reduced, thereby assuring flat morphology and a uniform circuit pattern.

A further advantage of the present invention is that a second electroless copper plating layer is plated in a desired thickness in a via hole, thereby preventing interruption of an internal circuit of the via hole after an electrolytic copper plating layer is formed.

Yet another advantage of the present invention is that since the fine via hole, in which the internal circuit is not interrupted, can be formed, a highly dense PCB may be provided.

What is claimed is:

1. A printed circuit board, comprising:
an insulating layer;
at least one via hole formed through the insulating layer;
a first electroless plating layer which is formed on a wall of the via hole and on at least one side of the insulating layer so as to have a predetermined pattern, wherein the first electroless plating layer is etched at an edge portion corresponding to an edge portion of the pattern in a dimension that is in proportion to a thickness of the first electroless plating layer;
a second electroless plating layer formed on the first electroless plating layer; and
an electrolytic plating layer formed on the second electroless plating layer and etched at an edge portion in a dimension that is in proportion to the thickness of the first electroless plating layer.

2. The printed circuit board as set forth in claim 1, wherein the first electroless plating layer is thinner than the second electroless plating layer.

3. The printed circuit board as set forth in claim 2, wherein a thickness of the first electroless plating layer is about 0.1-0.5 μm, and a thickness of the second electroless plating layer is about 1-5 μm.

4. The printed circuit board as set forth in claim 1, wherein each of the first electroless plating layer, the second electroless plating layer, and the electrolytic plating layer comprises a material, selected from the group consisting of Cu, Au, Ni, Sn, and an alloy thereof, as a main component.

5. A method of fabricating a printed circuit board, comprising the steps of:
(A) laminating an insulating layer on a substrate, on which a circuit pattern is formed, and forming a via hole through the insulating layer for connection to the circuit pattern;
(B) forming a first electroless plating layer on an exposed portion of the circuit pattern, the insulating layer, and a wall of the via hole;
(C) forming a predetermined plating resist pattern on the first electroless plating layer, and forming a second electroless plating layer on a portion of the first electroless plating layer, on a different portion of the first electrolesss ;lating layer separate from the plating resist pattern;
(D) forming an electrolytic plating layer on the second electroless plating layer, and removing the plating resist pattern; and
(E) removing the remaining portion of the first electroless plating layer, separate from both the second electroless plating layer and the electrolytic plating layer.

6. The method as set forth in claim 5, wherein the first electroless plating layer is formed using a catalyst precipitation process in the step (B).

7. The method as set forth in claim 5, wherein the first electroless plating layer is formed using a sputtering process in the step (B).

8. The method as set forth in claim 5, wherein the second electroless plating layer is formed using the first electroless plating layer as a self-catalyst in the step (C).

9. The method as set forth in claim 5, wherein the electrolytic plating layer is formed using the first electroless plating layer as an incoming line for plating in the step (D).

10. The method as set forth in claim 5, wherein the first electroless plating layer is formed thinner than the second electroless plating layer of the step (C) in the step (B).

11. The method as set forth in claim 10, wherein a thickness of the first electroless plating layer is about 0.1-0.5 μm, and a thickness of the second electroless plating layer is about 1-5 μm.

12. The method as set forth in claim 5, wherein each of the first electroless plating layer, the second electroless plating layer, and the electrolytic plating layer comprises a material, selected from the group consisting of Cu, Au, Ni, Sn, and an alloy thereof, as a main component.
